(19) United States
(12) Patent Application Publication
(10) Pub. No.: US 2025/0349368 A1
(43) Pub. Date: Nov. 13, 2025

(54) MEMORY DEVICE INCLUDING A VOLTAGE SWITCHING CIRCUIT

(71) Applicant: SK hynix Inc., Icheon-si Gyeonggi-do (KR)

(72) Inventors: Jin Ho KIM, Icheon-si Gyeonggi-do (KR); Chang Woo KANG, Icheon-si Gyeonggi-do (KR); Hyeon Jae KIM, Icheon-si Gyeonggi-do (KR); Seung Jun LEE, Icheon-si Gyeonggi-do (KR); Jung Hoon LEE, Icheon-si Gyeonggi-do (KR)

(73) Assignee: SK hynix Inc., Icheon-si Gyeonggi-do (KR)

(21) Appl. No.: 18/882,127

(22) Filed: Sep. 11, 2024

(30) Foreign Application Priority Data
May 7, 2024 (KR) 10-2024-0059581

(51) Int. Cl. G11C 16/30; G11C 16/08; G11C 16/24

(52) U.S. Cl. CPC G11C 16/30; G11C 16/08; G11C 16/24

(57) ABSTRACT

A memory device includes a first semiconductor layer including a memory cell array which is connected to word lines extending in a first direction and bit lines extending in a second direction substantially perpendicular to the first direction; and a second semiconductor layer disposed under the first semiconductor layer, and including a first area overlapping the first semiconductor layer in a third direction substantially perpendicular to the first and second directions and a second area overlapping the first area in the first direction, the second semiconductor layer including a row decoder disposed in the second area, and including pass transistors; and a first voltage switching circuit configured to transmit an operating voltage to the pass transistors, and including switching elements, wherein at least one switching element among the switching elements is disposed in the second area to overlap the pass transistors in the first direction.

### CROSS-REFERENCE TO RELATED APPLICATION

The present application claims priority under 35 U.S.C. § 119(a) to Korean Patent Application No. 10-2024-0059581 filed in the Korean Intellectual Property Office on May 7, 2024, which application is incorporated herein by reference in its entirety.

### BACKGROUND

### 1. Technical Field

Embodiments of the disclosed technology generally relate to a memory device, and more particularly, to a memory device including a voltage switching circuit.

### 2. Related Art

A three-dimensional memory device having memory cells which are three-dimensionally arranged has been proposed. The three-dimensional memory device has advantages in that a larger capacity may be realized within the same area by stacking memory cells in a vertical direction to increase the number of stacks to highly integrate memory cells, thereby providing high performance and excellent power efficiency.

### SUMMARY

In an embodiment, a memory device may include: a first semiconductor layer including a memory cell array which is connected to a plurality of word lines extending in a first direction and a plurality of bit lines extending in a second direction substantially perpendicular to the first direction; and a second semiconductor layer disposed under the first semiconductor layer, and including a first area overlapping the first semiconductor layer in a third direction substantially perpendicular to the first direction and the second direction and a second area overlapping the first area in the first direction, the second semiconductor layer including: a row decoder disposed in the second area, and including a plurality of pass transistors; and a first voltage switching circuit configured to transmit an operating voltage to the plurality of pass transistors, and including a plurality of switching elements, wherein at least one switching element among the plurality of switching elements is disposed in the second area to overlap the plurality of pass transistors in the first direction.

In an embodiment, a memory device may include: a first semiconductor layer including a memory cell array which is connected to a plurality of word lines extending in a first direction and a plurality of bit lines extending in a second direction substantially perpendicular to the first direction; and a second semiconductor layer disposed under the first semiconductor layer, and including a first area overlapping the first semiconductor layer in a third direction substantially perpendicular to the first direction and the second direction and a second area overlapping the first area in the first direction, the second semiconductor layer including: a page buffer circuit disposed in the first area, and connected to the plurality of bit lines; a row decoder disposed in the second area, and including a plurality of pass transistors; and a first voltage switching circuit configured to transmit an operating voltage to the plurality of pass transistors, and including a plurality of switching elements, wherein at least one switching element among the plurality of switching elements is disposed in the second area to overlap the page buffer circuit in the first direction.

In an embodiment, a memory device may include: a first semiconductor layer including a memory cell array which is connected to a plurality of word lines extending in a first direction and a plurality of bit lines extending in a second direction substantially perpendicular to the first direction; and a second semiconductor layer disposed under the first semiconductor layer, the second semiconductor layer including: a page buffer circuit connected to the plurality of bit lines; a row decoder connected to the plurality of word lines, and including a plurality of pass transistors; and a first voltage switching circuit configured to transmit an operating voltage to the plurality of pass transistors, and including a plurality of switching elements, wherein at least one switching element among the plurality of switching elements is disposed between the plurality of pass transistors to overlap the plurality of pass transistors in the first direction.

### BRIEF DESCRIPTION OF THE DRAWINGS

FIG. 1 is a block diagram of a memory device based on an embodiment of the disclosed technology.

FIG. 2 is a perspective view of the memory device based on an embodiment of the disclosed technology.

FIG. 3 is a view illustrating an example of the planar structure of a second semiconductor layer of FIG. 2.

FIG. 4 is a diagram illustrating an example of a switching unit included in a first voltage switching circuit.

FIG. 5 is a view illustrating an example of a part of the configuration illustrated in FIG. 3.

FIG. 6 is a view illustrating another example of the planar structure of the second semiconductor layer of FIG. 2.

FIG. 7 is a view illustrating an example of a structure in which the second semiconductor layer of FIG. 6 is expanded.

FIGS. 8A and 8B are views illustrating an example of a circuit structure in the second semiconductor layer of FIG. 6.

FIGS. 9 and 10 are views illustrating still other examples of the planar structure of the second semiconductor layer of FIG. 2.

FIG. 11 is a diagram illustrating an example of a second voltage switching circuit.

### DETAILED DESCRIPTION

Hereinafter, various embodiments of the present disclosure will be described in detail with reference to accompanying drawings. Spatially relative terms, such as “under,” “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under,” “below” or “beneath” other elements or features would then be oriented “above” the other elements or features. Thus, the example of the term “under” can encompass both an orientation of above and below. The device may be otherwise oriented (rotated 90 degrees or at other orientations) and the spatially relative descriptors used herein interpreted accordingly.

Various embodiments of the disclosed technology are directed to providing a memory device capable of high integration.

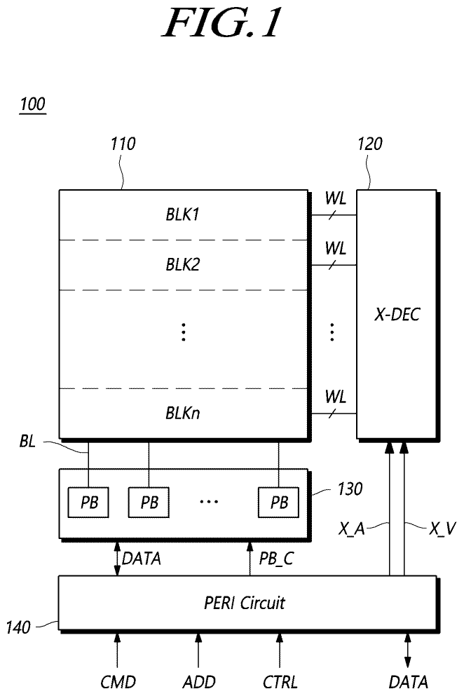

FIG. 1 is a block diagram of a memory device based on an embodiment of the disclosed technology.

Referring to FIG. 1, the memory device 100 based on an embodiment of the disclosed technology includes a memory cell array 110, a row decoder (X-DEC) 120, a page buffer circuit 130 and a peripheral circuit (PERI circuit) 140.

The memory cell array 110 may include a plurality of memory blocks BLK1 to BLKn (n is a natural number of 2 or greater). Each of the memory blocks BLK1 to BLKn may include a plurality of cell strings. Each of the cell strings may include at least one drain select transistor, a memory cell array and at least one source select transistor which are connected in series. Each memory cell may be a volatile memory cell or may be a nonvolatile memory cell. While it is described below that the memory device 100 is a vertical NAND flash device, it is to be understood that the technical idea of the disclosed technology is not limited thereto.

The row decoder 120 is connected to the memory cell array 110 through word lines WL.

The row decoder 120 selects any one among the memory blocks BLK1 to BLKn included in the memory cell array 110, in response to a row address X_A provided from the peripheral circuit 140. The row decoder 120 transmits an operating voltage X_V provided from the peripheral circuit 140, to word lines WL connected to a memory block selected among the memory blocks BLK1 to BLKn included in the memory cell array 110.

The memory cell array 110 is connected to the page buffer circuit 130 through bit lines BL. The page buffer circuit 130 includes a plurality of page buffers PB which are connected to the bit lines BL, respectively. The page buffer circuit 130 receives a page buffer control signal PB_C from the peripheral circuit 140, and transmits and receives a data signal DATA to and from the peripheral circuit 140. The page buffer circuit 130 may control the bit lines BL, which are arranged in the memory cell array 110, in response to the page buffer control signal PB_C. For example, the page buffer circuit 130 may detect data, stored in a memory cell of the memory cell array 110, by sensing the signal of a bit line BL of the memory cell array 110 in response to the page buffer control signal PB_C, and may transmit the data signal DATA to the peripheral circuit 140 according to the detected data. The page buffer circuit 130 may apply a signal to a bit line BL on the basis of the data signal DATA, received from the peripheral circuit 140, in response to the page buffer control signal PB_C, and accordingly, may write data to a memory cell of the memory cell array 110. The page buffer circuit 130 may write or read data to or from a memory cell which is connected to a word line activated by the row decoder 120.

The peripheral circuit 140 receives a command signal CMD, an address signal ADD and a control signal CTRL from outside the memory device 100, and transmits and receives data DATA to and from a device outside the memory device 100, for example, a memory controller. The peripheral circuit 140 outputs signals for writing data to the memory cell array 110 or reading data from the memory cell array 110, for example, the row address X_A and the page buffer control signal PB_C, based on the command signal CMD, the address signal ADD and the control signal CTRL. The peripheral circuit 140 may generate various voltages including the operating voltage X_V, which are required in the memory device 100.

Hereinbelow, in the accompanying drawings, two directions that are parallel to the upper surface of a first semiconductor layer or a second semiconductor layer are defined as a first direction FD and a second direction SD, respectively, and a direction that vertically protrudes from the upper surface of the first semiconductor layer or the second semiconductor layer is defined as a third direction VD. For example, the first direction FD may correspond to the extending direction of word lines, and the second direction SD may correspond to the extending direction of bit lines. The first direction FD and the second direction SD may be substantially perpendicular to each other. The third direction VD is a direction that is perpendicular to the first direction FD and the second direction SD. In the following description, the term ‘vertical’ or ‘vertical direction’ will be used as substantially the same meaning as the third direction VD. In the drawings, a direction indicated by an arrow and a direction opposite thereto represent the same direction.

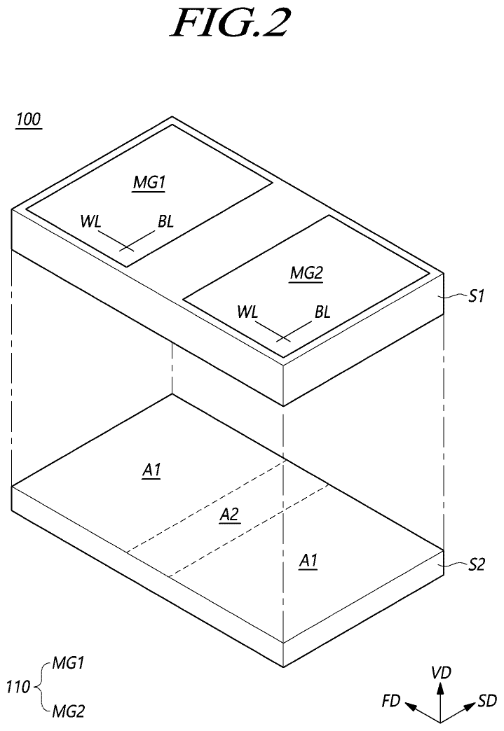

FIG. 2 is a perspective view of the memory device based on an embodiment of the disclosed technology.

Referring to FIG. 2, the memory device 100 includes a first semiconductor layer S1 and a second semiconductor layer S2. The first semiconductor layer S1 and the second semiconductor layer S2 overlap each other in the vertical direction VD. For example, the second semiconductor layer S2 is disposed under the first semiconductor layer S1 in the vertical direction VD.

The first semiconductor layer S1 includes the memory cell array 110. The memory cell array 110 may be divided into a first memory group MG1 and a second memory group MG2. Although not illustrated, the first memory group MG1 may include a plurality of first sub-blocks, and the second memory group MG2 may include a plurality of second sub-blocks. One first sub-block and one second sub-block corresponding thereto constitute one memory block BLK.

The first memory group MG1 and the second memory group MG2 are arranged in the first direction FD. A plurality of word lines WL and a plurality of bit lines BL are connected to each of the first memory group MG1 and the second memory group MG2. The plurality of word lines WL extend in the first direction FD and are arranged in the second direction SD, and the plurality of bit lines BL extend in the second direction SD and are arranged in the first direction FD.

The second semiconductor layer S2 includes a pair of first areas A1 and a second area A2 between the first areas A1. The second area A2 overlaps the first areas A1 in the first direction FD.

The first semiconductor layer S1 and the second semiconductor layer S2 may be manufactured on different wafers, and then, may be bonded to each other through a wafer bonding process to be unified. In this case, the memory device 100 may be defined as having a POC (peripheral over cell) structure.

The first semiconductor layer S1 and the second semiconductor layer S2 may be built up on a single wafer. Although not illustrated, the second semiconductor layer S2 may include a substrate, various semiconductor elements which are formed on the substrate, and wirings which are connected to the semiconductor elements. The second semiconductor layer S2 may include a plurality of pass transistors, a block selection circuit, a page buffer circuit, a plurality of voltage switching circuits, and circuits corresponding to a peripheral circuit. After forming various circuits in the second semiconductor layer S2, a memory cell array may be formed on the second semiconductor layer S2, and wirings for electrically connecting the memory cell array and the circuits formed in the second semiconductor layer S2 may be formed. In this case, the memory device 100 may be defined as having a PUC (peripheral under cell) structure.

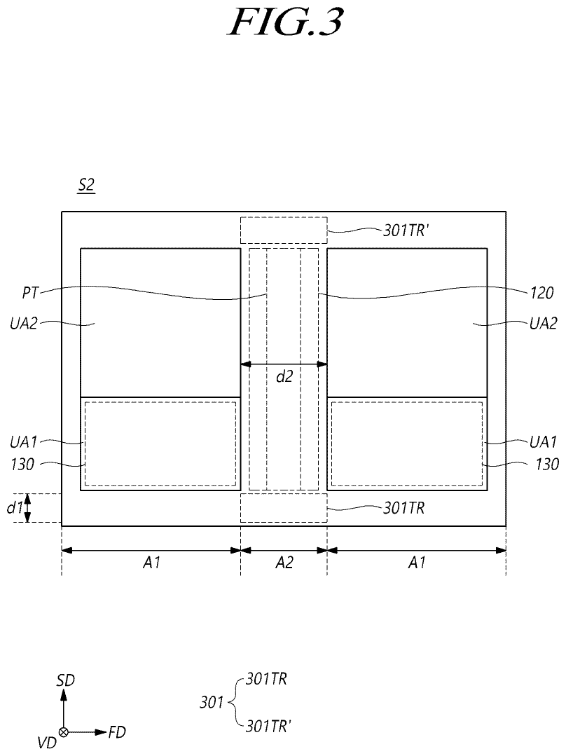

FIG. 3 is a view illustrating an example of the planar structure of a second semiconductor layer of FIG. 2.

Referring to FIG. 3, each of the first areas A1 includes a first under cell area UA1 and a second under cell area UA2. The first under cell area UA1 and the second under cell area UA2 overlap each of the first memory group MG1 and the second memory group MG2 in the vertical direction VD. The first under cell area UA1 and the second under cell area UA2 overlap each other in the second direction SD. The combined area of the first under cell area UA1 and the second under cell area UA2 may correspond to an area where the first memory group MG1 is disposed or an area where the second memory group MG2 is disposed. The fact that two areas correspond to each other means that the areas of the two areas are substantially the same or similar.

The page buffer circuit 130 is disposed in the first under cell areas UA1 of the first areas A1. The page buffer circuit 130 overlaps the first memory group MG1 and the second memory group MG2 in the vertical direction VD.

Peripheral circuits excluding the page buffer circuit 130 and a row decoder 120 may be disposed in the second under cell areas UA2 of the first areas A1.

As in an example illustrated in FIG. 3, the second area A2 is located between the two first areas A1. The width of the second area A2 in the first direction FD is d2. The row decoder 120 may be disposed in an area of the second area A2 which overlaps the first under cell areas UA1 and the second under cell areas UA2 in the first direction FD.

A first voltage switching circuit 301 is disposed in an area of the second area A2 which does not overlap the first under cell areas UA1 and the second under cell areas UA2 in the first direction FD. The first voltage switching circuit 301 is a circuit which transmits various voltages received from the peripheral circuit to the plurality of pass transistors PT. The first voltage switching circuit 301 may include a plurality of switching units. Each of the plurality of switching units is connected to one global word line. Each of the plurality of switching units transmits various voltages received from the peripheral circuit to a pass transistor PT through the global word line. Because the plurality of switching units are connected one-to-one with global word lines, the number of the plurality of switching units may be the same as the number of the global word lines. A plurality of first transistors 301TR and a plurality of second transistors 301TR′ are transistors which are included in the plurality of switching units. Each of the plurality of switching units includes one transistor among the plurality of first transistors 301TR and one transistor among the plurality of second transistors 301TR′. The length, in the second direction SD, of an area where the plurality of first transistors 301TR are disposed is d1. In an embodiment, the length, in the second direction SD, of an area where the plurality of second transistors 301TR′ are disposed may also be d1.

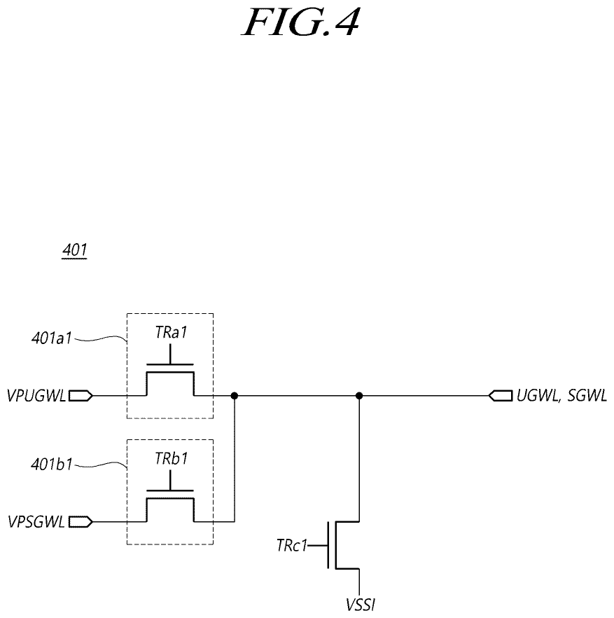

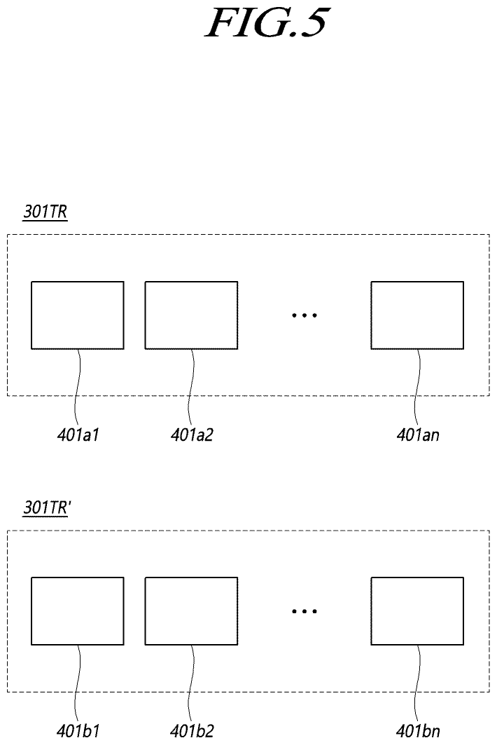

FIG. 4 is a diagram illustrating an example of a switching unit included in a first voltage switching circuit. FIG. 5 is a view illustrating an example of a part of the configuration illustrated in FIG. 3.

Referring to FIGS. 4 and 5, a first switching unit 401 may include a first transistor TRa1, a second transistor TRb1 and a third transistor TRc1.

Hereinafter, the first transistor TRa1 will be referred to as a first switching element 401a1, and the second transistor TRb1 will be referred to as a second switching element 401b1.

The plurality of first transistors 301TR include first switching elements 401a1 to 401an which are included in the switching units, respectively. The plurality of second transistors 301TR′ include second switching elements 401b1 to 401bn.

The plurality of first switching elements 401a1 to 401an receive an unselected global word line voltage VPUGWL from the peripheral circuit, and are controlled according to a control signal. The unselected global word line voltage VPUGWL may be a voltage which is transmitted to an unselected global word line UGWL.

The plurality of second switching elements 401b1 to 401bn receive a selected global word line voltage VPSGWL from the peripheral circuit, and are controlled according to a control signal different from the control signal which controls the plurality of first switching elements 401a1 to 401an. The selected global word line voltage VPSGWL may be a voltage which is transmitted to a selected global word line SGWL. The selected global word line voltage VPSGWL may be transmitted from the peripheral circuit.

The third transistor TRc1 receives an internal power supply voltage VSSI, and is controlled according to a control signal different from the control signals which control the first switching element 401a1 and the second switching element 401b1.

According to the first switching unit 401, the selected global word line voltage VPSGWL, the unselected global word line voltage VPUGWL and the internal power supply voltage VSSI may be selectively transmitted to one of the global word lines.

Referring to FIGS. 3 and 4, in the area of the second area A2 which does not overlap the first under cell areas UA1 and the second under cell areas UA2 in the first direction FD, the plurality of first switching elements 401a1 to 401an and the plurality of second switching elements 401b1 to 401bn are disposed. The plurality of first switching elements 401a1 to 401an are disposed in an area of the second area A2 which is adjacent to the first under cell areas UA1 in the second direction SD and does not overlap the second under cell areas UA2. The plurality of second switching elements 401b1 to 401bn are disposed in an area of the second area A2 which is adjacent to the second under cell areas UA2 in the second direction SD and does not overlap the first under cell areas UA1. In an embodiment, the plurality of first switching elements 401a1 to 401an are disposed in an area of the second area A2 which is adjacent to the first under cell areas UA1 in the second direction SD and does not overlap the second under cell areas UA2 in the first direction FD or the first under cell area UA1 in the first direction FD. In an embodiment, the plurality of second switching elements 401b1 to 401bn are disposed in an area of the second area A2 which is adjacent to the second under cell areas UA2 in the second direction SD and does not overlap the first under cell areas UA1 in the first direction FD or the second under cell area UA2 in the first direction FD. In an embodiment, the plurality of first switching elements 401a1 to 401an are disposed in an area of the second area A2 which is adjacent to the first under cell areas UA1 in the second direction SD and does not overlap the second under cell areas UA2 in the second direction SD or the first under cell area UA1 in the second direction SD. In an embodiment, the plurality of second switching elements 401b1 to 401bn are disposed in an area of the second area A2 which is adjacent to the second under cell areas UA2 in the second direction SD and does not overlap the first under cell areas UA1 in the second direction SD or the second under cell area UA2 in the second direction SD.

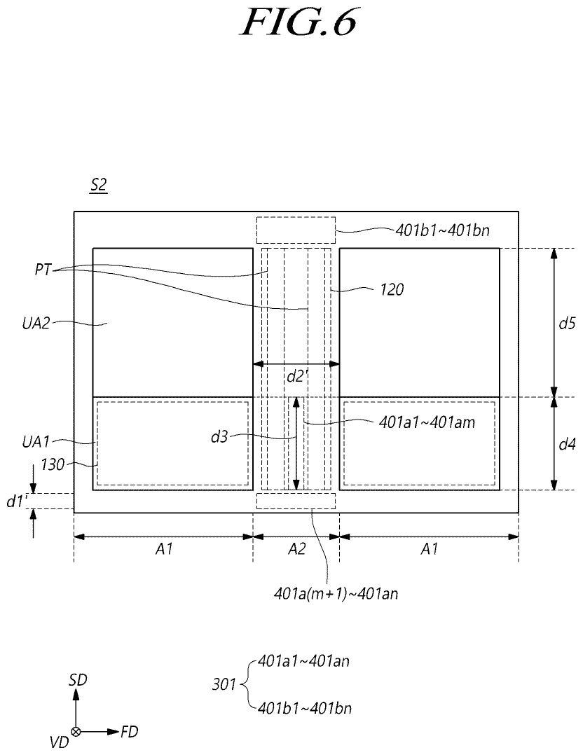

FIG. 6 is a view illustrating an example of the planar structure of the second semiconductor layer of FIG. 2.

Referring to FIG. 6, at least some of the plurality of switching units of a first voltage switching circuit 301 may be disposed in an area of the second area A2 which overlaps first under cell areas UA1 in the first direction FD. As used herein, the phrase ‘at least some’ includes one or more.

More specifically, at least some of a plurality of first switching elements 401a1 to 401an (for example, 401a1 to 401am, m is a natural number smaller than n) included in the switching units of the first voltage switching circuit 301 overlap the first under cell areas UA1 in the first direction FD. However, the embodiments of the disclosed technology is not limited thereto, and some of the first switching elements 401a1 to 401an may also overlap the second under cell areas UA2 in the first direction FD. As used herein, the tilde “˜” indicates a range of components. For example, “401a1˜401an” indicates the first switching elements 401a1, 401a2, . . . , and 401an shown in FIG. 6.

Because the page buffer circuit 130 is disposed in the first under cell areas UA1, at least some switching units (or at least some switching elements) overlap the page buffer circuit 130 in the first direction FD.

At least some of the plurality of switching units of the first voltage switching circuit 301 overlap, in the first direction FD, the row decoder 120 which is disposed in the second area A2. More specifically, at least some of the plurality of first switching elements 401a1 to 401am (m is a natural number smaller than n) included in the switching units of the first voltage switching circuit 301 may be located between a plurality of pass transistors PT included in the row decoder 120 while overlapping the plurality of pass transistors PT in the first direction FD.

In particular, at least some of plurality of the first switching elements 401a1 to 401an may be located on the same line as at least one of the plurality of pass transistors PT in the first direction FD.

As at least some switching units (or at least some switching elements) are disposed between the plurality of pass transistors PT in the second area A2, the length of the second area A2 in the first direction FD increases compared to a case where no switching unit (or no switching element) is disposed between the plurality of pass transistors PT. That is to say, d2′ is larger than d2. In an embodiment, the width of the second area A2 in the first direction FD is d2′ as shown in FIG. 6. That is to say, the width of the second area A2 in the first direction FD increases from d2 as shown in FIGS. 3 to d2′ as shown in FIG. 6.

On the other hand, as at least some of the plurality of first switching elements 401a1 to 401an are disposed in the second area A2 to overlap the first under cell areas UA1 in the first direction FD, the number of a plurality of first switching elements 401a1 to 401an (for example, 401a(m+1) to 401an, m is a natural number smaller than n) disposed in an area of the second area A2 which does not overlap the first under cell areas UA1 in the first direction FD may decrease. Accordingly, the length, in the second direction SD, of the area where, among the plurality of first switching elements 401a1 to 401an, transistors which do not overlap the first under cell areas UA1 in the first direction FD are disposed decreases compared to a case where all of the first switching elements 401a1 to 401an do not overlap the first under cell areas UA1. That is to say, d1′ is smaller than d1. In an embodiment, the length, in the second direction SD, of an area where the plurality of first voltage switching circuits 401a1 to 401an that do not overlap with the first under cell area UA1 in the first direction are disposed is d1′ as shown in FIG. 6. In an embodiment, the length, in the second direction SD, of an area where the plurality of second voltage switching circuits 401b1 to 401bn are disposed may be d1.

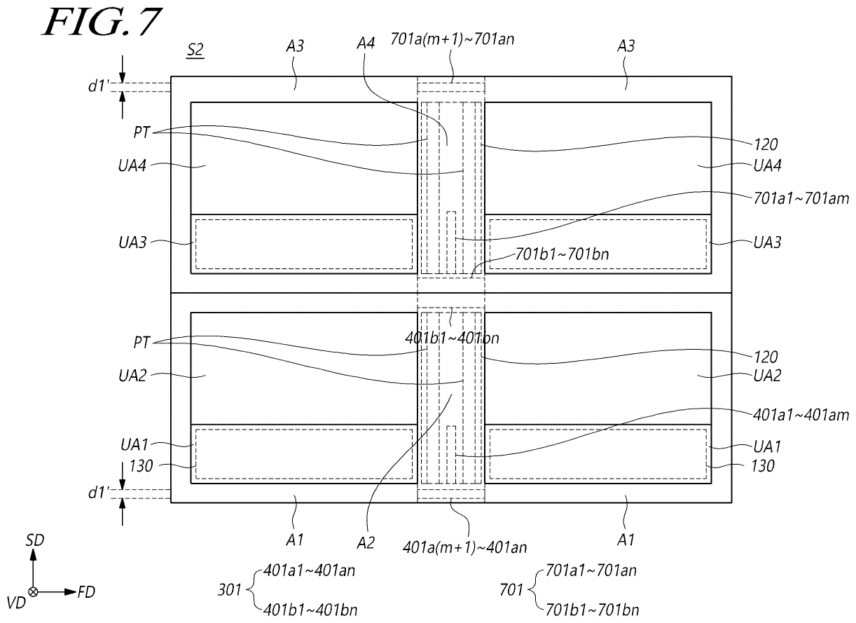

In an embodiment, a length d3 in the second direction of an area where the at least some of a plurality of first switching elements 401a1 to 401an (for example, 401a1 to 401am, m is a natural number smaller than n) overlap the plurality of pass transistors PT in the first direction is smaller than a sum of a length d4 in the second direction of the first under cell area UA1 and a length d5 in the second direction of the second under cell area UA2. In an embodiment, the sum of a length d4 in the second direction of the first under cell area UA1 and a length d5 in the second direction of the second under cell area UA2 may be substantially the same as a length in the second direction of an area where the row decoder 120 is disposed. FIG. 7 is a view illustrating an example of a structure in which the second semiconductor layer of FIG. 6 is expanded.

Referring to FIG. 7, the second semiconductor layer S2 includes first areas A1, a second area A2, third areas A3 and a fourth area A4.

The second area A2 is located between the first areas A1, and overlaps the first areas A1 in the first direction FD. The fourth area A4 is located between the third areas A3, and overlaps the third areas A3 in the first direction FD. The second area A2 and the fourth area A4 overlap each other in the second direction SD.

Each of the first areas A1 includes a first under cell area UA1 and a second under cell area UA2. Each of the third areas A3 includes a third under cell area UA3 and a fourth under cell area UA4. The first under cell area UA1 and the second under cell area UA2 overlap in the second direction SD. The third under cell area UA3 and the fourth under cell area UA4 overlap in the second direction SD.

A page buffer circuit 130 is disposed in the first under cell areas UA1 and the third under cell areas UA3. The page buffer circuit 130 which is disposed in the first under cell areas UA1 is connected, through bit lines, to memory groups which overlap the first areas A1 in the vertical direction VD. The page buffer circuit 130 which is disposed in the third under cell areas UA3 is connected, through bit lines, to memory groups which overlap the third areas A3 in the vertical direction VD.

A row decoder 120 is disposed in the second area A2 and the fourth area A4. As described above, the row decoder 120 includes a plurality of pass transistors PT. A plurality of pass transistors PT which are disposed in the second area A2 are connected, through word lines, to the memory groups which overlap the first areas A1 in the vertical direction VD. A plurality of pass transistors PT which are disposed in the fourth area A4 are connected, through word lines, to the memory groups which overlap the third areas A3 in the vertical direction VD.

A first voltage switching circuit 301 is disposed in the second area A2. A third voltage switching circuit 701 is disposed in the fourth area A4. The first voltage switching circuit 301 is a circuit which transmits various voltages received from a peripheral circuit to the plurality of pass transistors PT disposed in the second area A2. The third voltage switching circuit 701 is a circuit which transmits various voltages received from the peripheral circuit to the plurality of pass transistors PT disposed in the fourth area A4.

The first voltage switching circuit 301 and the third voltage switching circuit 701 may each include a plurality of switching units. The switching units of the first voltage switching circuit 301 include a plurality of first switching elements 401a1 to 401an and a plurality of second switching elements 401b1 to 401bn. The switching units of the third voltage switching circuit 701 include a plurality of third switching elements 701a1 to 701an and a plurality of fourth switching elements 701b1 to 701bn. Each of the switching units of the first voltage switching circuit 301 includes one of the plurality of first switching elements 401a1 to 401an and one of the plurality of second switching elements 401b1 to 401bn. Each of the switching units of the third voltage switching circuit 701 includes one of the plurality of third switching elements 701a1 to 701an and one of the plurality of fourth switching elements 701b1 to 701bn.

Each of the plurality of switching units is connected to one global word line. Each of the plurality of switching units is a circuit which transmits various voltages received from the peripheral circuit to a pass transistor PT through the global word line. Because the plurality of switching units are connected one-to-one with global word lines, the number of the plurality of switching units may be the same as the number of the global word lines.

At least some of the plurality of switching units of the first voltage switching circuit 301 are disposed in an area of the second area A2 which overlaps the first under cell areas UA1 in the first direction FD. At least some of the plurality of switching units of the third voltage switching circuit 701 are disposed in an area of the fourth area A4 which overlaps the third under cell areas UA3 in the first direction FD.

More specifically, at least some of the plurality of first switching elements 401a1 to 401an (for example, 401a1 to 401am, m is a natural number smaller than n) are disposed in an area of the second area A2 which overlaps the first under cell areas UA1 in the first direction FD. At least some of the plurality of third switching elements 701a1 to 701an (for example, 701a1 to 701am, m is a natural number smaller than n) are disposed in an area of the fourth area A4 which overlaps the third under cell areas UA3 in the first direction FD.

Because the page buffer circuit 130 is disposed in the first under cell areas UA1 and the third under cell areas UA3, at least some switching units (or at least some switching elements) overlap the page buffer circuit 130 in the first direction FD.

At least some of the plurality of switching units of the first voltage switching circuit 301 overlap, in the first direction FD, the row decoder 120 which is disposed in the second area A2. More specifically, at least some of the plurality of first switching elements 401a1 to 401an included in the switching units of the first voltage switching circuit 301 may be located between a plurality of pass transistors PT included in the row decoder 120 while overlapping the plurality of pass transistors PT in the first direction FD.

At least some of the plurality of switching units of the third voltage switching circuit 701 overlap, in the first direction FD, the row decoder 120 which is disposed in the fourth area A4. More specifically, at least some of the plurality of third switching elements 701a1 to 701an included in the switching units of the third voltage switching circuit 701 may be located between a plurality of pass transistors PT included in the row decoder 120 while overlapping the plurality of pass transistors PT in the first direction FD.

As at least some switching elements of the plurality of first switching elements 401a1 to 401an are disposed in the second area A2 to overlap the first under cell areas UA1 in the first direction FD, the number of a plurality of first switching elements 401a1 to 401an disposed in an area of the second area A2 which does not overlap the first under cell areas UA1 in the first direction FD may decrease. Therefore, the length, in the second direction SD, of the area where switching elements which do not overlap the first under cell areas UA1 in the first direction FD among the plurality of first switching elements 401a1 to 401an are disposed decreases compared to a case where all of the plurality of first switching elements 401a1 to 401an do not overlap the first under cell areas UA1. That is to say, d1′ is smaller than d1.

In addition, as at least some switching elements of the plurality of third switching elements 701a1 to 701an are disposed in the fourth area A4 to overlap the third under cell areas UA3 in the first direction FD, the number of a plurality of third switching elements 701a1 to 701an disposed in an area of the fourth area A4 which does not overlap the third under cell areas UA3 in the first direction FD may decrease. Therefore, the length, in the second direction SD, of the area where switching elements which do not overlap the third under cell areas UA3 in the first direction FD among the plurality of third switching elements 701a1 to 701an are disposed decreases compared to a case where all of the plurality of third switching elements 701a1 to 701an do not overlap the third under cell areas UA3. That is to say, d1′ is smaller than d1.

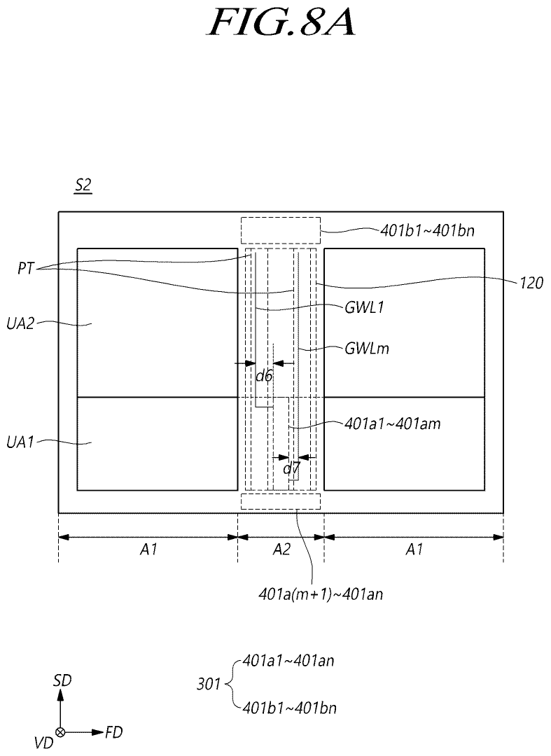

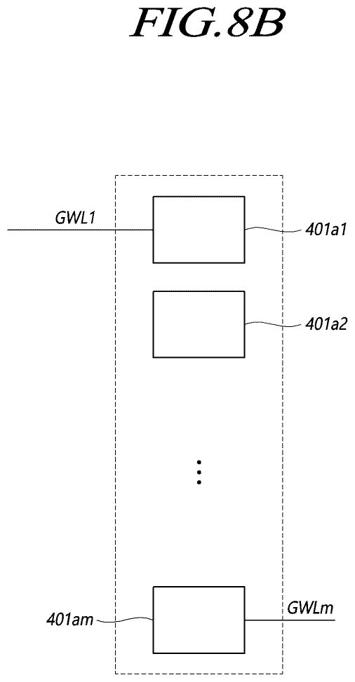

FIGS. 8A and 8B are views illustrating an example of a circuit structure in the second semiconductor layer of FIG. 6.

Referring to FIG. 8A, each of the plurality of first switching elements 401a1 to 401an is connected to one global word line. As described above, because each switching unit is connected to one global word line, switching elements included in the switching unit may be connected to the same one global word line.

For example, among the switching units, a switching unit which is located closest to the second under cell areas UA2 in the second direction SD may be connected to a first global word line GWL1. Among the switching units, a switching unit which is located farthest from the second under cell areas UA2 in the second direction SD may be connected to an mth global word line GWLm. Here, m is a natural number smaller than n.

The first global word line GWL1 and the mth global word line GWLm are connected to pass transistors PT, respectively, which are disposed in an area of the second area A2 located farthest from the first under cell areas UA1 in the second direction SD.

The first global word line GWL1 may be connected to a pass transistor PT which is located near the edge of the area of the second area A2 located farthest from the first under cell areas UA1 in the second direction SD, and the mth global word line GWLm may be connected to a pass transistor PT which is located near the center of the area of the second area A2 located farthest from the first under cell areas UA1 in the second direction SD. In other words, the length d6 of the first global word line GWL1 in the first direction FD may be larger than the length d7 of the mth global word line GWLm in the first direction FD.

Referring to FIG. 8B, the global word lines may be connected to the plurality of first switching elements 401a1 to 401an, respectively. For example, the first global word line GWL1 may be connected to the first switching element 401a1 which is located closest to the second under cell areas UA2 in the second direction SD. The mth global word line GWLm may be connected to the first switching element 401am which is located farthest from the second under cell areas UA2 in the second direction SD.

In an embodiment, the sum of the lengths in the first direction FD and the second direction SD of the first global word line GWL1 may be substantially the same as the sum of the lengths in the first direction FD and the second direction SD of the mth global word line GWLm. Namely, depending on the location of a switching element, by setting differently the lengths in the first direction FD and the second direction SD of a global word line connected to the switching element to make the overall length of each global word line constant, even in the case where the switching elements are disposed to overlap the first under cell areas UA1 in the first direction FD, a change in resistance due to a change in the length of a global word line may be, in an embodiment, minimized.

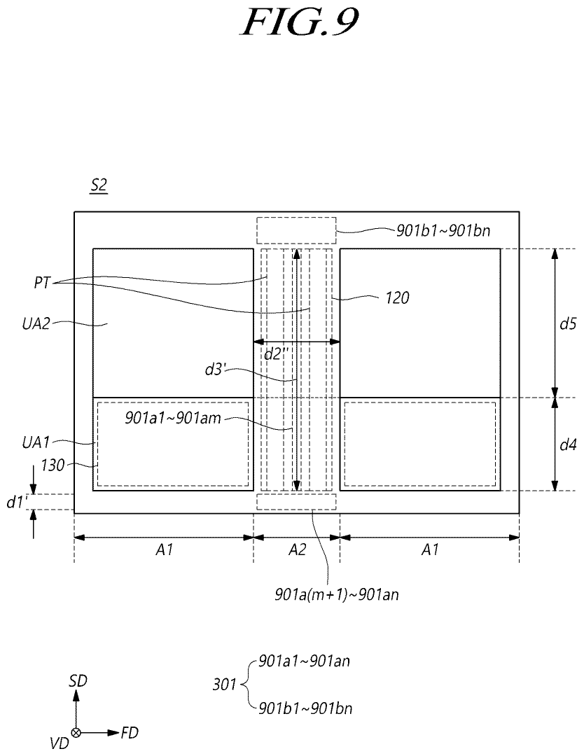

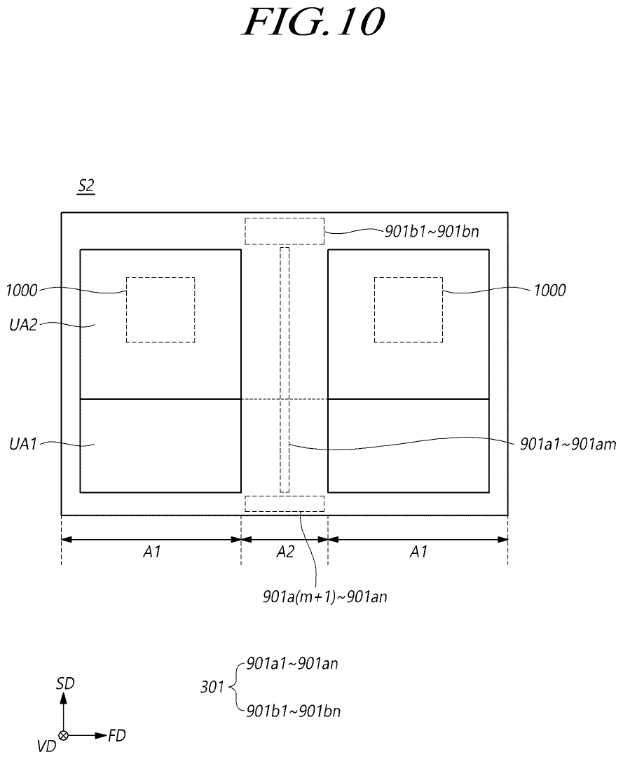

FIGS. 9 and 10 are views illustrating still other examples of the planar structure of the second semiconductor layer of FIG. 2.

In describing these examples, description for components substantially the same as those of the previous examples will be omitted.

Referring to FIG. 9, at least some of the plurality of switching units of a first voltage switching circuit 301 located in the second area A2 overlap, in the first direction FD the first under cell areas UA1 and the second under cell areas UA2 located in the first area A1.

More specifically, at least some of a plurality of first switching elements 901a1 to 901an (for example, 901a1 to 901am, m is a natural number smaller than m) located in the second area A2 included in the switching units overlap, in the first direction FD, the first under cell areas UA1 and the second under cell areas UA2 located in the first area A1.

The length d3′ in the second direction of an area where the at least some of a plurality of first switching elements 901a1 to 901an (for example, 901a1 to 901am, m is a natural number smaller than n) overlap the plurality of pass transistors PT in the first direction may be substantially the same as the sum of the lengths d4, d5 in the second direction SD of the first under cell area UA1 and the second under cell area UA2.

Because at least some switching units are disposed not only in an area of the second area A2 which overlaps the first under cell areas UA1 in the first direction FD but also in an area of the second area A2 which overlaps the second under cell areas UA2 in the first direction FD, compared to a case where switching units overlap only the first under cell areas UA1 in the second area A2, an amount by which the length of the second area A2 in the first direction FD increases is small. That is to say, d2″ is smaller than d2′.

Referring to FIG. 10, a second voltage switching circuit 1000 is disposed in the second under cell areas UA2. The second voltage switching circuit 1000 is a circuit which transmits various voltages to the first voltage switching circuit 301. Referring to FIGS. 9 and 10, there are a plurality of second switching elements 901b1 to 901bn.

At least some switching units overlap the second voltage switching circuit 1000 in the first direction FD.

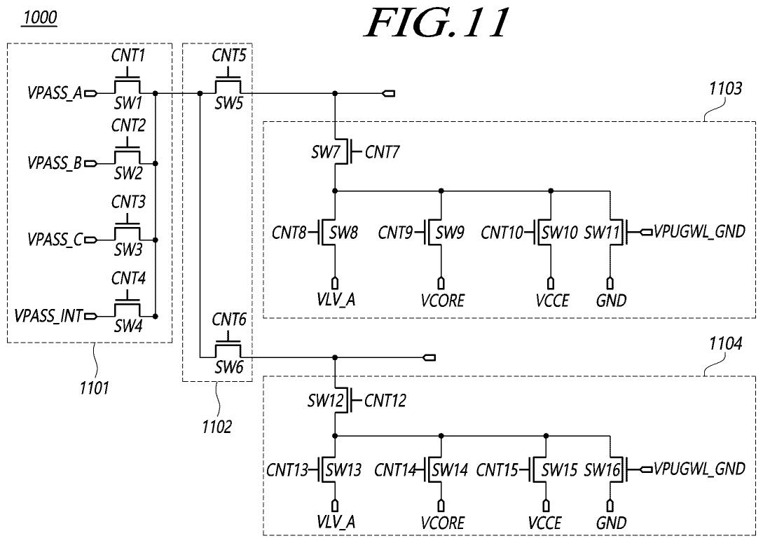

FIG. 11 is a diagram illustrating an example of a second voltage switching circuit.

Referring to FIG. 11, the second voltage switching circuit 1000 includes a first circuit block 1101, a second circuit block 1102, a third circuit block 1103 and a fourth circuit block 1104. The first circuit block 1101 includes first to fourth switches SW1 to SW4. The first to fourth switches SW1 to SW4 are controlled by first to fourth control signals CNT1 to CNT4, respectively. The second circuit block 1102 includes fifth and sixth switches SW5 and SW6. The fifth and sixth switches SW5 and SW6 are controlled by fifth and sixth control signals CNT5 and CNT6, respectively. The third circuit block 1103 includes seventh to eleventh switches SW7 to SW11. The fourth circuit block 1104 includes twelfth to sixteenth switches SW12 to SW16. The seventh to tenth switches SW7 to SW10 are controlled by seventh to tenth control signals CNT7 to CNT10, respectively. The twelfth to fifteenth switches SW12 to SW15 are controlled by twelfth to fifteenth control signals CNT12 to CNT15, respectively. The eleventh and sixteenth switches SW11 and SW16 are controlled by an unselected ground control signal VPUGWL_GND.

By the second voltage switching circuit 1000 illustrated in FIG. 11, pass voltages VPASS_A to VPASS_C, an initialization voltage VPASS_INT, an internal low voltage VLV_A, an external power supply voltage VCCE, a core voltage VCORE and a ground voltage GND are transmitted to the first voltage switching circuit 301 illustrated in FIG. 10. More specifically, by the first circuit block 1101, the second circuit block 1102 and the third circuit block 1103, the pass voltages VPASS_A to VPASS_C, the initialization voltage VPASS_INT, the internal low voltage VLV_A, the external power supply voltage VCCE, the core voltage VCORE and the ground voltage GND are transmitted to the first voltage switching circuit 301 illustrated in FIG. 10 as unselected global word line voltages.

Meanwhile, by the first circuit block 1101, the second circuit block 1102 and the fourth circuit block 1104, the internal low voltage VLV_A, the external power supply voltage VCCE, the core voltage VCORE and the ground voltage GND are transmitted to the first voltage switching circuit 301 as unselected global word line voltages.

Referring once again to FIG. 6, at least some switching units included in the first voltage switching circuit 301, more specifically, at least some of the plurality of first switching elements 401a1 to 401an which are included in the switching units and receive unselected global word line voltages may be disposed in an area of the second area A2 which overlaps the first under cell areas UA1 in the first direction FD.

According to an embodiment of the disclosed technology, as at least some of the plurality of switching elements included in the switching units of the first voltage switching circuit 301 are disposed in an area which overlaps the first under cell areas UA1 in the first direction FD, the length in the second direction SD of an area of the second area A2 which does not overlap the first under cell areas UA1 and the second under cell areas UA2 in the first direction FD may be reduced. Accordingly, in an embodiment, because the gap between memory groups may be further narrowed, it is possible to implement a memory device capable of high integration.

The above description has been presented to enable any person skilled in the art to make, use and practice the technical features of the disclosed technology, and has been provided in the context of a particular application and its requirements as examples. Various modifications, additions and substitutions to the described embodiments will be readily apparent to those skilled in the art, and the principles described herein may be applied to other embodiments and applications without departing from the scope of the disclosed technology. Therefore, the embodiments disclosed above and in the accompanying drawings should be considered in a descriptive sense only and not for limiting the technological scope. The technological scope of the disclosed technology is not limited by the embodiments and the accompanying drawings. The spirit and scope of the disclosed technology should be interpreted in connection with the appended claims and encompass all equivalents falling within the scope of the appended claims.

What is claimed is:

1. A memory device comprising:
a first semiconductor layer including a memory cell array, the memory cell array connected to a plurality of word lines extending in a first direction and a plurality of bit lines extending in a second direction substantially perpendicular to the first direction; and
a second semiconductor layer disposed under the first semiconductor layer, and including a first area overlapping the first semiconductor layer in a third direction substantially perpendicular to the first direction and the second direction and a second area overlapping the first area in the first direction,
the second semiconductor layer comprising:
a row decoder disposed in the second area, and including a plurality of pass transistors; and
a first voltage switching circuit configured to transmit an operating voltage to the plurality of pass transistors, and including a plurality of switching elements, wherein at least one switching element among the plurality of switching elements is disposed in the second area to overlap the plurality of pass transistors in the first direction.

2. The memory device according to claim 1, further comprising:
a page buffer circuit disposed in the first area, and connected to the plurality of bit lines,
wherein the at least one switching element overlaps the page buffer circuit in the first direction.

3. The memory device according to claim 2,
wherein the first area includes a first under cell area where the page buffer circuit is disposed and a second under cell area overlapping the first under cell area in the second direction, and
wherein the at least one switching element overlaps the first under cell area in the first direction.

4. The memory device according to claim 3,
wherein the plurality of switching elements include a switching element which is located closest to the second under cell area in the second direction and a switching element which is located farthest from the second under cell area in the second direction, and
wherein a length in the first direction of a global word line connected to the switching element which is located closest to the second under cell area in the second direction is larger than a length in the first direction of a global word line connected to the switching element which is located farthest from the second under cell area in the second direction.

5. The memory device according to claim 1, wherein
wherein the plurality of switching elements include a first switching element configured to output an unselected global word line voltage to a global word line and a second switching element configured to output a selected global word line voltage to a global word line, and
wherein the first switching element overlaps the plurality of pass transistors in the first direction.

6. The memory device according to claim 1, further comprising:
a page buffer circuit disposed in the first area, and connected to the plurality of bit lines,
wherein the first area includes a first under cell area where the page buffer circuit is disposed and a second under cell area overlapping the first under cell area in the second direction, and
wherein the at least one switching element overlaps the first under cell area and the second under cell area in the first direction.

7. The memory device according to claim 6, wherein a length in the second direction of an area where the at least one switching element overlaps the plurality of pass transistors in the first direction is the same as a sum of a length in the second direction of the first under cell area and a length in the second direction of the second under cell area.

8. The memory device according to claim 6, further comprising:
a second voltage switching circuit disposed in the first area, and configured to transmit an unselected global word line voltage and a selected global word line voltage to the first voltage switching circuit,
wherein the second voltage switching circuit overlaps the at least one switching element in the first direction.

9. The memory device according to claim 1, further comprising:
a page buffer circuit disposed in the first area, and connected to the plurality of bit lines,
wherein the first area includes a first under cell area where the page buffer circuit is disposed and a second under cell area overlapping the first under cell area in the second direction, and
wherein at least the other one of the plurality of switching element is disposed in an area of the second area except an area overlapping the first under cell area in the first direction and an area overlapping the second under cell area in the first direction.

10. A memory device comprising:
a first semiconductor layer including a memory cell array, the memory cell array connected to a plurality of word lines extending in a first direction and a plurality of bit lines extending in a second direction substantially perpendicular to the first direction; and
a second semiconductor layer disposed under the first semiconductor layer, and including a first area overlapping the first semiconductor layer in a third direction substantially perpendicular to the first direction and the second direction and a second area overlapping the first area in the first direction,
the second semiconductor layer comprising:
a page buffer circuit disposed in the first area, and connected to the plurality of bit lines;
a row decoder disposed in the second area, and including a plurality of pass transistors; and
a first voltage switching circuit configured to transmit an operating voltage to the plurality of pass transistors, and including a plurality of switching elements, wherein at least one switching element among the plurality of switching elements is disposed in the second area to overlap the page buffer circuit in the first direction.

11. The memory device according to claim 10,
wherein the first area includes a first under cell area where the page buffer circuit is disposed and a second under cell area overlapping the first under cell area in the second direction, and
wherein the at least one switching element overlaps the first under cell area in the first direction.

12. The memory device according to claim 10,
wherein the plurality of switching units include a first switching element configured to output an unselected global word line voltage to a global word line and a second switching element configured to output a selected global word line voltage to a global word line, and
wherein the first switching element overlaps the plurality of pass transistors in the first direction.

13. The memory device according to claim 12, wherein the first switching element is located on the same line as at least one of the plurality of pass transistors in the first direction.

14. The memory device according to claim 10,
wherein the first area includes a first under cell area where the page buffer circuit is disposed and a second under cell area overlapping the first under cell area in the second direction, and
wherein the at least one switching element overlaps the first under cell area and the second under cell area in the first direction.

15. A memory device comprising:
a first semiconductor layer including a memory cell array, the memory cell array connected to a plurality of word lines extending in a first direction and a plurality of bit lines extending in a second direction substantially perpendicular to the first direction; and
a second semiconductor layer disposed under the first semiconductor layer,
the second semiconductor layer comprising:
a page buffer circuit connected to the plurality of bit lines;
a row decoder connected to the plurality of word lines, and including a plurality of pass transistors; and
a first voltage switching circuit configured to transmit an operating voltage to the plurality of pass transistors, and including a plurality of switching elements, wherein at least one switching element among the plurality of switching elements is disposed between the plurality of pass transistors to overlap the plurality of pass transistors in the first direction.

16. The memory device according to claim 15, wherein the at least one switching element overlaps the page buffer circuit in the first direction.

17. The memory device according to claim 15, wherein a length in the second direction of an area where the at least one switching element overlaps the plurality of pass transistors in the first direction is smaller than a length in the second direction of an area where the row decoder is disposed.

18. The memory device according to claim 15, wherein a length in the second direction of an area where the at least one switching element overlaps the plurality of pass transistors in the first direction is substantially the same as a length in the second direction of an area where the row decoder is disposed.
